(19) United States
(12) Patent Application Publication
(10) Pub. No.: US 2015/0147952 A1
(43) Pub. Date: May 28, 2015

(54) AIR PASSAGE DEVICE FOR ADMITTING PURIFIED AIR INTO AN INTERIOR OF A CONTROL CABINET

(71) Applicants: Andreas Pfannenberg, Hamburg (DE); Peter Starp, Hamburg (DE)

(72) Inventors: Andreas Pfannenberg, Hamburg (DE); Peter Starp, Hamburg (DE)

(73) Assignee: Pfannenberg GmbH, Hamburg (DE)

(21) Appl. No.: 14/552,917

(22) Filed: Nov. 25, 2014

(30) Foreign Application Priority Data
Nov. 25, 2013 (DE) 102013112977.3

(51) Int. Cl. H05K 7/20

(52) U.S. Cl. CPC H05K 7/20009
USPC 454/184

(57) ABSTRACT

In order to arrange an air passage device for the admission and purification of air, in particular ambient air, into the interior of a control cabinet or computer housing in such a way that the device can be used also in an environment which is subject to an increased degree of pollution, a first purifying includes a centrifugal separator.

### CROSS-REFERENCE TO RELATED APPLICATIONS

This application is entitled to the benefit of and incorporates by reference essential subject matter disclosed in German Patent Application No. 102013112977.3 filed on Nov. 25, 2013.

### FIELD OF THE INVENTION

The invention relates to an air passage device for admitting air, in particular ambient air, into an interior of a control cabinet or a computer housing, in particular a server housing, wherein the air, before being admitted into the interior of the control cabinet or the computer housing, is purified.

Further the invention relates to a control cabinet with an air passage device for admitting the purified air into its interior.

### BACKGROUND OF THE INVENTION

Control cabinets comprise electric and/or electronic components of a process plant, a machine or a production facility, wherein these components are normally not arranged directly in the machine.

The electric and/or electronic components arranged in the control cabinet are protected by the control cabinet above all against dust, aerosols and humidity. Furthermore the interior of a control cabinet must be protected against overheating.

It is customary to protect the interior of a control cabinet against overheating through the use of control cabinet air conditioning systems such as cooling aggregates or heat exchangers. Or, depending on the environment in which the control cabinet is used, it may be sufficient to use filter fans or cooling air openings with fan. In particular in environments exposed to pollution by dust or aerosols such as solid or liquid suspended particles in the atmosphere, cooling air openings with fans or filter fans are not suitable. Dust particles, aerosols as well as moisture can get into the interior of the cabinet through the openings in it. In the case of filter fans there is a need for continuously replacing the filter materials due to the increased dust or aerosol content in the ambient air.

Therefore, in environments exposed to increased pollution by dust or aerosols and/or increased humidity enclosed control cabinets or completely enclosable control cabinets are used which are cooled by means of additional cooling aggregates or heat exchangers. Ambient air can thus not enter into the interior of the control cabinet. Computers, mainframes or servers are also used in dusty environments as well as in environments with higher air humidity. Therefore the same problem as with control cabinets occurs with the cooling of the interior of computer housings.

### SUMMARY OF THE INVENTION

It is the requirement of the invention to propose an air passage device for admitting purified air, in particular ambient air, into the interior of a control cabinet or a computer housing, which can be used in environments exposed to higher pollution.

Pollution is understood to mean any pollution of the air, in particular a higher degree of pollution. In particular this includes pollution by dust and aerosols, air laden with oil or emulsion-containing air.

According to the invention an air passage device for admitting air, in particular ambient air, into an interior of a control cabinet or a computer housing is proposed, wherein the air passage device comprises a first air purifying means for purifying the air to be passed through the air passage device. Furthermore an air conveying means for admitting the air to be purified in the first air purifying means, into the first air purifying means is arranged on or in the housing of the air passage device. Furthermore, according to the invention the air passage device comprises a housing. The first air purifying means is configured as a centrifugal separator.

The air passage device may be configured so as to be completely enclosed or only partially enclosed due to the housing. The air passage device may preferably be arranged on or in the area of a control cabinet or a computer housing.

A control cabinet is understood to be a housing with electric and/or electronic components of a process plant, a machine tool or a production facility, wherein these electric and/or electronic components are preferably not directly arranged on the machine. Furthermore the air passage device is configured for admitting air, in particular ambient air, into an interior of a computer housing, in particular a server housing.

At least one first air purifying means is provided for purifying the air, in particular ambient air, prior to its entry into the interior of a control cabinet or a computer housing. The first air purifying means is configured as a centrifugal separator. Further the first air purifying means is preferably arranged in the interior of the air passage device, wherein the interior of the air passage device is isolated or enclosed by the housing of the air passage device. Preferably the first air purifying means does not comprise a filter, in particular a filter element such as a filter mat.

Preferably only a first air purifying means and thus no further air purifying means is provided. Preferably no filter, e.g. in particular no filter element such as a filter mat, is provided in the air passage device so that this is configured completely without filter.

The centrifugal separator may, for example, be configured as a cyclone separator. The centrifugal separator serves to separate solid or liquid particles contained in gases (such as ambient air). Thus dusty ambient air can be cleaned using the centrifugal separator. The air as a carrier is set into rotary motion by its own flow velocity and an appropriate constructive design of the centrifugal separator. The centrifugal forces acting upon the particles contained in the air accelerate the particles radially outwards. This causes them to be separated from the air flow, whereby the air flow is directed inwards and then discharged.

Preferably the centrifugal separator comprises an inflow cylinder in the upper area and a cone-shaped section in the central area and/or the lower area. Furthermore the centrifugal separator preferably comprises a particle-collecting receptacle in the lower area. In the centre an immersion tube is arranged which protrudes into the inflow cylinder from above. The air is admitted into the inflow cylinder in the upper area. Due to the fact that dirt particles and air are separated inside the inflow cylinder, or in the cone-shaped section arranged below the inflow cylinder, the dirt particles are caught in the particle-collecting receptacle and accumulated therein. The at least partially cleaned air, from which the particles have been separated, rises through the immersion tube to the top.

By providing the air passage device with a centrifugal separator as a first air purifying means, the interior of a control cabinet or a computer housing can be cooled through the admittance of purified air. As a result there is no need for a more elaborate and expensive air conditioning system such as a cooling aggregate or a heat transmitter, e.g. a heat exchanger. By providing a centrifugal separator as a first air purifying means frequent replacement of filter elements is avoided. The particle-collecting receptacle of a centrifugal separator is suitable for collecting dirt particles over a longer period of time than is possible with filter elements such as filter mats, for example. This is of advantage, in particular, in heavily polluted atmospheres. Furthermore the particle-collecting receptacle of the centrifugal separator can be emptied in a simple manner. There is no need here for replacing a filter element. Thus the provision of an air passage device with a centrifugal separator, is cost-effective even during operation, and low-maintenance.

Further it is advantageous that by using an air passage device configured without filter, a device can be provided which does not suffer from pressure losses or at least pressure reductions. Arrangements known from the state of the art with filter elements such as filter mats suffer from loss of pressure just because of the filter element. As dirt accumulates on the filter element in such arrangements the loss of pressure increases.

Preferably the air passage device comprises a first air inlet opening for the intake of air into the interior of the air passage device. The air to be purified can be admitted through the first air inlet opening to the air passage device. Furthermore provision is preferably made for the air passage device to comprise a first air outlet opening for the discharge of purified air. The purified air can be directed out of the interior of the air passage device through the first air outlet opening and passed into the interior of the control cabinet or computer housing.

Preferably both the first air inlet opening and the first air outlet opening are arranged in the housing of the air passage device. The first air inlet opening and the first air outlet opening may be arranged at any suitable location of the housing of the air passage device. It is particularly preferred if the first air inlet opening and the first air outlet opening are arranged in the upper and/or lower half of the housing of the air passage device. Thus it is particularly preferable that both the first air inlet opening and the first air outlet opening are not arranged centrally in the housing of the air passage device. Furthermore provision is preferably made for the first air inlet opening and the first air outlet opening to be arranged in different halves of the housing of the air passage device, in particular at opposite ends from one another. For example the first air inlet opening may be arranged in the upper area or in the upper half of the housing of the air passage device, and the first air outlet opening may be arranged in the lower area, or in the lower half of the housing of the air passage device.

Further, the first air inlet opening and the first air outlet opening are preferably arranged on different side walls. For example, the first air outlet opening could be arranged on a first side wall of the housing of the air passage device and the first air outlet opening could be arranged on a second side wall of the housing of the air passage device.

The first air inlet opening as well as the first air outlet opening could comprise any suitable shape or any suitable cross-section. Preferably the first air inlet opening and/or the first air outlet opening might comprise a round, oval or box-type cross-section, for example a rectangular or square cross-section.

It is preferred if the air passage device is essentially cube-shape. To this end the air passage device preferably comprises a height which is greater than the width and/or depth. Preferably the air passage device or the housing of the air passage device comprises a height in the range between 200 mm and 2000 mm, especially preferably between 400 mm and 1800 mm. Further the air passage device preferably comprises a width between 200 mm and 600 mm, especially preferably between 250 mm and 500 mm. Furthermore the depth is preferably between 100 mm and 600 mm, especially preferably between 150 mm and 300 mm.

The first air purifying means may be arranged in any suitable manner within the air passage device. The first air purifying means comprises an inlet opening through which the air to be purified is admitted to the first air purifying means. For example the first air purifying means may be arranged directly on an inside wall of the air passage device. The first air purifying means is arranged with its first inlet opening in the area of the first air inlet opening of the air passage device. In this way the air to be purified can flow directly through the first air inlet opening of the air passage device and through the inlet opening of first air purifying means. Preferably the first air purifying means within the air passage device is arranged at a distance from the side walls of the air passage device. Further provision is preferably made for the first air inlet opening of the air passage device to be connected via an entry duct with the inlet opening of the first air purifying means for forwarding the air to the first air purifying means.

Further provision is preferably made for the first air purifying means to comprise several centrifugal separators. For example, two centrifugal separators may be provided. Furthermore provision is preferably made for between one and twelve centrifugal separators. The individual centrifugal separators may be arranged inside the housing of the first air purifying means or separately in the interior of the air passage device. The individual centrifugal separators may be arranged one behind the other in flow direction. The air to be purified flows through all the centrifugal separators one after the other. In this way a multi-stage purification can be achieved through the first air purifying means. Alternatively or additionally several centrifugal separators may be arranged in parallel to one another. The parallel arrangement refers to the air flow. With a parallel arrangement of several centrifugal separators the air to be purified can enter essentially simultaneously into the individual centrifugal separators. Furthermore this allows the air which is to be purified to be distributed among several centrifugal separators. Provision may be made for a common air inlet duct and/or air outlet duct for the individual centrifugal separators. For example the first air purifying means could be configured to be multi-stage, wherein in a first stage one centrifugal separator is provided, and following on from this in flow direction, a second stage is provided with one or more centrifugal separators arranged in parallel to each other. Also several centrifugal separators arranged in parallel could be provided in the first stage. Further, more than two stages could be provided.

The entry duct which connects the first air inlet opening of the air passage device with the inlet opening of the first air purifying means may comprise any suitable shape, or any suitable cross-section. For example, the entry duct may be shaped tube-like or hose-like or as a tube or a hose. The entry duct may comprise a round, oval or box section. The inlet opening of the first air purifying means is preferably arranged in the upper area of the first air purifying means, i.e. at least in the upper half of the first air purifying means. Thus the inlet opening of the centrifugal separator is arranged in the area of the inflow cylinder as well as in the upper area of the inflow cylinder.

The first air inlet opening of the air passage device and the inlet opening of the first air purifying means may be identical in shape or in cross-section, or be shaped differently or may have different cross-sectional areas. For example the first air inlet opening of the air passage device and/or the inlet opening of the first air purifying means may comprise a round, oval or box cross-section. Preferably the first air inlet opening of the air passage device may be larger than the inlet opening of the first air purifying means. By this is understood that the first air outlet opening has a larger cross-section or a larger opening area than the inlet opening of the first air purifying means. For example the first air inlet opening may have a larger width and/or height than the inlet opening of the first air purifying means.

Further the entry duct is preferably configured such that its cross-section decreases from the first air inlet opening in direction of the inlet opening of the first air purifying means. Especially preferably the cross-section of the entry duct decreases continuously. By continuous is understood that the cross-section from the first air inlet opening in direction of the inlet opening of the first air purifying means does not increase in any area. Thus the cross-section of the entry duct decreases from the first air inlet opening in direction of the inlet opening of the first air purifying means in all areas or remains at least constant in sections. For example the entry duct may be cone-shaped, tapered or funnel-shaped.

The inlet opening of the first air purifying means or the entry duct is preferably arranged so as to be offset relative to a longitudinal central axis of the first air purifying means or relative to a longitudinal central axis of the inflow cylinder of the first air purifying means. Thus provision is preferably made for the air supply to the first air purifying means to be arranged not centrally but tangentially. The air to be purified is thus supplied to first air purifying means tangentially, i.e. in the lateral area of the inflow cylinder of the first air purifying means. Due to the tangential inflow the air in relation to the longitudinal central axis of the first air purifying means or in relation to the longitudinal central axis of the inflow cylinder of the first air purifying means, is not supplied centrally into the inflow cylinder of the first air purifying means but is directed in an offset manner to the inside wall of the inflow cylinder of the first air purifying means. By longitudinal central axis of the first air purifying means or longitudinal central axis of the inflow cylinder of the first air purifying means is understood the centrally arranged longitudinal axis of the first air purifying means or of the inflow cylinder of the first air purifying means. Preferably the first air purifying means in its longitudinal direction is arranged vertically within the air passage device. Thus preferably provision is made for the inlet opening of the first air purifying means or the entry duct relative to the vertical central axis of the first air purifying means, or relative to the vertical central axis of the inflow cylinder of the first air purifying means to be arranged in an offset manner.

Besides the entry duct is preferably formed in such a manner that an end region of the entry duct protrudes into the first air purifying means. Thus provision is preferably made for the entry duct, over a first length, to protrude through the inlet opening of the first air purifying means, into the first air purifying means. The entry duct may be formed of one or more pieces. Further the end region of the entry duct, in the area of the first length, may comprise any suitable shape or any suitable cross-section. For example the end region of the entry duct, over the entire first length, may comprise a constant or decreasing cross-section. Preferably the end region of the entry duct is cylindrically shaped over the first length thereof. Furthermore provision is preferably made for the first length, along which the entry duct with its end region protrudes into the first air purifying means, to be smaller than half the diameter of the inflow cylinder of the first air purifying means in the region of the inlet opening of the first air purifying means. Also, provision is preferably made for the entry duct with its end region to be arranged within the inflow cylinder of the first air purifying means, at a distance from the immersion tube.

Preferably the end region of the entry duct protruding into the first air purifying means is arranged offset to the tangential inflow of the air into the inflow cylinder of the first air purifying means in relation to the longitudinal central axis of the first air purifying means and/or in relation to the longitudinal central axis of the inflow cylinder of the first air purifying means.

Further provision is preferably made for the end region of the entry duct protruding into the first air purifying means to be arranged so as to incline downwards, e.g. creased or bent downwards. Further the entry duct may be arranged in an oblique downward direction over its entire length. The longitudinal central axis of the entry duct and/or a side wall of the entry duct is therefore, at least in a section, not arranged vertically to the side wall of the inflow cylinder of the first air purifying means. That means that the longitudinal central axis of the entry duct and/or a side wall of the entry duct, at least in sections, is at an angle to the side wall of the inflow cylinder of the first air purifying means, wherein this angle is smaller than 90°. Thus the entry duct, at least in an end region thereof, is shaped such that air admittance into the inflow cylinder of the first air purifying means is arranged, not vertically to the inside wall of the inflow cylinder, but at an angle smaller than 90° to the inside wall of the inflow cylinder of the first air purifying means.

The interior of the air passage device preferably comprises at least two areas. The first area is spatially separated from the second area of the interior of the air passage device by a separating means. The two areas of the interior of the air passage device may be arranged side by side or especially preferred one on top of the other. First and second areas refer to the direction of the air flow through the air passage device. Thus in flow direction the second area is arranged behind the first area.

The separating means may comprise any suitable shape or any suitable material. For example, the separating means may be configured as a partition, a metal sheet or similar. The air flow through the air passage device is preferably envisaged to be through both areas. The first air purifying means is preferably arranged in the first area of the interior of the air passage device. The air to be purified is initially supplied to the first air purifying means in the first area. After the first purifying step the air purified by the first air purifying means is passed into the second area of the interior of the air passage device and from there is discharged through the first air outlet opening, i.e. is supplied to a control cabinet or computer housing.

The separating means preferably comprises one or preferably several air passage apertures. Thus the separating means is arranged in the interior of the air passage device for spatially separating the first area from the second area, but it comprises air passage apertures to allow the air flowing through both areas of the interior of the air passage device. For example, the separating means may in sections be configured as a grid. Especially preferably the separating means may be configured as a grid in the centre, but closed in the edge regions. Preferably the separating means is connected in an airtight manner with the housing or the housing inside walls. Therefore the air flow from the first area into the second area is preferably exclusively limited to the air passage apertures arranged in the separating means.

Further a fan is preferably arranged on the separating means which serves as an air conveying means. The air conveying means may be arranged in the first area or in the second area. Preferably provision is made for the separating means to be firmly connected to the air conveying means. The separating means therefore serves as a holder for the air conveying means, e.g. a fan. Especially preferably the air conveying means is arranged in the area of the air passage apertures of the separating means.

Besides it is preferred that the interior of the air passage device is under negative pressure relative to the environment. At least one area of the interior of the air passage device, is under negative pressure relative to the environment. If a separating means does not exist, the entire interior of the air passage device is preferably under negative pressure relative to the environment.

The interior of the air passage device may be under negative pressure in relation to the interior of the control cabinet or the computer housing. For example, the interior of the air passage device may comprise a negative pressure in one area relative to the interior of the control cabinet or the computer housing. If a separating means does not exist, the entire interior of the air passage device is preferably under negative pressure relative to the environment. In this case the purified air is conveyed into the interior of the control cabinet or the computer housing by means of an air conveying means.

Preferably the first area of the interior of the air passage device is under negative pressure in relation to the environment (the area comprising the air to be purified), e.g. in relation to the ambient air outside the air passage device. Further provision is preferably made for the first area of the interior of the air passage device to comprise a negative pressure in relation to the second area of the interior of the air passage device. The expression “environment” is understood to means the area outside the air passage device, but not the interior of the control cabinet or the computer housing. Further “environment” also means the area which comprises the air to be purified or the air to be supplied to the air passage device. This may e.g. be the area of the ambient air.

The second area of the interior of the air passage device is preferably under positive pressure in relation to the interior of the control cabinet and/or in relation to the first area of the interior of the air passage device.

In addition to the first air purifying means the air passage device preferably comprises a second air purifying means. The second air purifying means is preferably arranged in the interior of the air passage device. The interior of the air passage device is arranged in flow direction behind the first air purifying means. Especially preferably the second air purifying means is arranged in the second area, e.g. in the positive pressure area, in flow direction behind the air conveying means. The first air purifying means is arranged in the first area of the interior of the air passage device and thus in the negative pressure area of the interior of the air passage device.

By providing a second air purifying means the air passage device may comprise two series-connected purifying stages. The first air purifying means may therefore be used for first rough purifying. The second air purifying means, which is arranged in inflow direction behind the first air purifying means, may be used for additional purifying, i.e. as a second purifying stage.

Preferably the second air purifying means comprises a filter, most particularly preferably an exchangeable filter insert such as a filter mat. Due to the fact that the second air purifying means has a first air purifying means arranged upstream of it for rough purifying, the filter element of the second air purifying means requires to be exchanged less frequently. If air purifying is carried out in such a two-stage arrangement savings on cost as well as waste can be achieved during operation of the air passage device. Further compared to devices known from the state of the art, expenditure is considerably less since a daily exchange of filter mats is no longer necessary due to having a first air purifying means arranged upstream. Nevertheless, by providing the second air purifying means the filtering achieved is at least equally effective. Due to the fact that a first, preferably filterless air purifying means is arranged upstream of the second purifying means preferably comprising a filter, the loss of pressure in the air passage device is much less than in arrangements equipped merely with filters. The reason for this is that it takes much longer for the filter element of the downstream filter to become clogged with dirt and impurities.

The second air purifying means is preferably configured as an exhaust filter or filter fan.

The second air purifying means may be arranged at any suitable location of the air passage device. For example the air passage device may be arranged in the area of the separating means between the first and the second area of the interior of the air passage device. Further the second air purifying means may be arranged in the second area, i.e. between the separating means and the first air outlet opening. Further the separating means may be arranged in the area of the first air outlet opening. Especially preferably the second air purifying means may be arranged as an exhaust filter or a filter fan in the area of the first air outlet opening. By exhaust filter is understood a filter without fan, and by filter fan is understood a filter with fan.

The air passage device preferably comprises a second air inlet opening for the inlet of air from the interior of the control cabinet into the interior of the air passage device. Further the air passage device preferably comprises a second air outlet opening for the outlet of air supplied from the interior of the control cabinet into the interior of the air passage device, preferably into the environment.

Preferably provision is made for the second air inlet opening and the second air outlet opening to be connected with each other by a warm air duct. In this way a spatial separation is achieved between the used air from the control cabinet and the cooler air which is cleaned in the air passage device and supplied to the control cabinet. The warm air duct may be configured in any suitable manner. Preferably the warm air duct extends from the second air inlet opening to the second air outlet opening through the interior of the air passage device. Especially preferably provision is made for the warm air duct to extend directly, i.e. along the shortest possible route, between the two openings, so that the length of the warm air duct can be kept as short as possible. Especially preferably the warm air duct extends horizontally. In this way provision is preferably made for the second air inlet opening and the second air outlet opening to be arranged in the housing at essentially the same level. For example the second air inlet opening and/or the second air outlet opening may be arranged in the upper or lower half of the housing of the air passage device. Preferably both the second air inlet opening and the second air outlet opening are not arranged in the central area of the housing of the air passage device. Further provision is preferably made for the second air inlet opening and the second air outlet opening to be arranged on different side walls of the housing of the air passage device. For example, the first air outlet opening and the second air inlet opening may be arranged on the same side wall of the housing of the air passage device.

Besides provision is preferably made for the second air outlet opening to be arranged on the top of and thus not on a side wall of the housing of the air passage device. In this way the warmer used air can be discharged upwards. This reduces the detrimental effect this used air would have upon persons in the area of the device.

The second air inlet opening, the second air outlet opening and the warm air duct linking the two openings may comprise any suitable shape, or any suitable cross-section. For example both openings as well as the warm air duct may have a round, oval or box-type cross-section. Further the warm air duct is preferably shaped so as to be completely enclosed. Warm air from the control cabinet or the computer housing can thus enter into the interior of the air passage device through the second air inlet opening, but leave the air passage device only via the second air outlet opening. In this way a spatial separation is ensured between the two air currents, the cooler supply air current and the warmer used air current. In order to avoid that the supply air current is heated by the warmer used air current, the warm air duct may comprise an insulating material. Further the warm air duct may comprise an additional heat insulation.

A filter element for filtering the used air may be arranged in the warm air duct and/or in the area of the second air inlet opening and/or in the area of the second air outlet opening.

Further provision is made according to the invention for a control cabinet with an above-described air passage device.

Preferably the air passage device is arranged on a control cabinet outside. The air passage device may be in direct contact with the control cabinet or with the control cabinet outside. Further the air passage device and the control cabinet may comprise a common side wall. This means that the air passage device and the control cabinet can share a side wall. Further the air passage device may be arranged recessed partly or across the entire depth thereof, the control cabinet.

### DESCRIPTION OF THE FIGURES

The invention will now be explained with reference to the accompanying drawings by way of especially preferred embodiments.

In the schematic drawings

FIG. 1 shows a perspective view of an air passage device with a centrifugal separator arranged inside it,

FIG. 2a shows a further perspective view of an air passage device, wherein the centrifugal separator arranged inside it is shown to be partially transparent,

FIG. 2b shows a further perspective view of an air passage device, wherein the centrifugal separator arranged inside it is shown to be partially transparent,

FIG. 3 shows a further perspective view of an air passage device, wherein the centrifugal separator arranged inside it is represented to be partially transparent, and

FIG. 4 shows a perspective view of a control cabinet with an air passage device arranged on the outer wall thereof.

### DETAILED DESCRIPTION OF THE PREFERRED EMBODIMENT

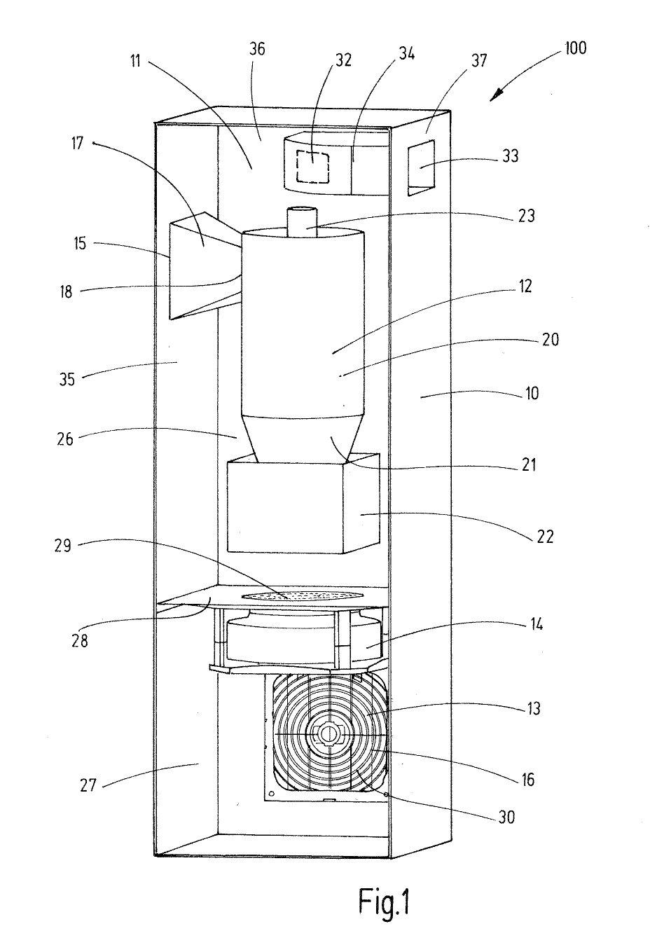

FIG. 1 shows an air passage device 100 for arranging in a control cabinet 200. The air passage device 100 of FIG. 1 is shown to be open on one side in order to be able to see the components arranged within. It means that the fourth side wall 38 of the air passage device 100 is not shown in FIG. 1.

The air passage device 100 comprises a housing 100 with four side walls 35, 36, 37, 38 as well as a topside and an underside. In the upper area of the air passage device 100 a first air inlet opening 15 is arranged in the first side wall 35 of the air passage device 100. The first air inlet opening 15 is connected via an entry duct 17 with the inlet opening 18 of the first air purifying means 12. The entry duct 17 from the first air purifying means 12 to the inlet opening 18 is shaped as a funnel. The first air inlet opening 15 of the air passage device 100 is thus larger than the inlet opening 18 of the first air purifying means 12.

The interior 11 of the air passage device 100 is separated into two areas 26, 27 by a separating means 28. The separating means 28 is shaped as a metal sheet with centrally arranged air passage apertures 29. On the underside of the separating means 28, i.e. in the second area 27 of the interior 11 of the air passage device 100, an air conveying means 14, i.e. a fan is arranged. Due to the spatial separation of the interior 11 of the air passage device 100 into two areas 26, 27 and the provision of an air conveying means 14 in the second area, the first area 26 of the interior 11 of the air passage device 100 is under negative pressure in relation to the ambient air. The second area 27 of the interior 11 of the air passage device 100 is under positive pressure in relation to the first area 26 as well as in relation to the interior 201 of the control cabinet 200.

In the first area 26 of the interior 11 of the air passage device 100 a first air purifying means 12, i.e. a centrifugal separator is arranged. In the second area 27 of the interior 11 of the air passage device 100 a second air purifying means 13, i.e. an exhaust filter 30, is arranged in the region of the first air outlet opening 16 of the air passage device 100.

The ambient air to be purified is sucked in from outside by the air conveying means 14 which is arranged on the separating means 28 in the second area 27 of the interior 11 of the air passage device 100. The ambient air enters through the first air inlet opening 15 and through the entry duct 17 into the upper area of the inflow cylinder 20 of the first air purifying means 12. Within the first air purifying means 12, i.e. within the centrifugal separator, the air to be purified, i.e. carrier, is set into a rotary motion through its own flow speed and the constructive design of the first air purifying means 12. The centrifugal force acting upon the dirt particles accelerates the dirt particles radially outwards. They are thus separated from the air current, wherein the air current is directed inwards and upwards towards the top through the immersion tube 23 of the first air purifying means 12 into the first area 26 of the interior 11 of the air passage device 100. Due to the negative pressure in the first area 26 of the interior 11 of the air passage device 100 the air current purified by the first air purifying means 12 is directed through the air passage aperture 29 of the separating means 28 into the second area 27 of the interior 11 of the air passage device 100. From the second area 27 of the interior 11 of the air passage device 100 the air purified in the first purifying stage by the first air purifying means 12 is conveyed through the first air outlet opening 16 in the lower area of the second side wall 36 of the housing 10 of the air passage device 100 to the control cabinet 200 or into the interior 201 of the control cabinet 200. Since a second air purifying means 13, i.e. an exhaust filter 30, is arranged in the area of the first air outlet opening 16 the air exiting from the interior 11 of the air passage device 100 is purified once more in a second stage.

In the upper area of the housing 10 of the air passage device 100 a second air inlet opening 32 is arranged in the second side wall 36 of the air passage device 100. The second air inlet opening 32 is connected by a warm air duct with a second air outlet opening 33 arranged in a third side wall 37 of the air passage device 100. Through this second air inlet opening 32 connected by a warm air duct with the second air outlet opening 33 the warm used air can be discharged from the interior 201 of the control cabinet 200 into the environment. By providing the warm air duct 34 this used air flow is spatially separated from the colder supply flow within the air passage device 100.

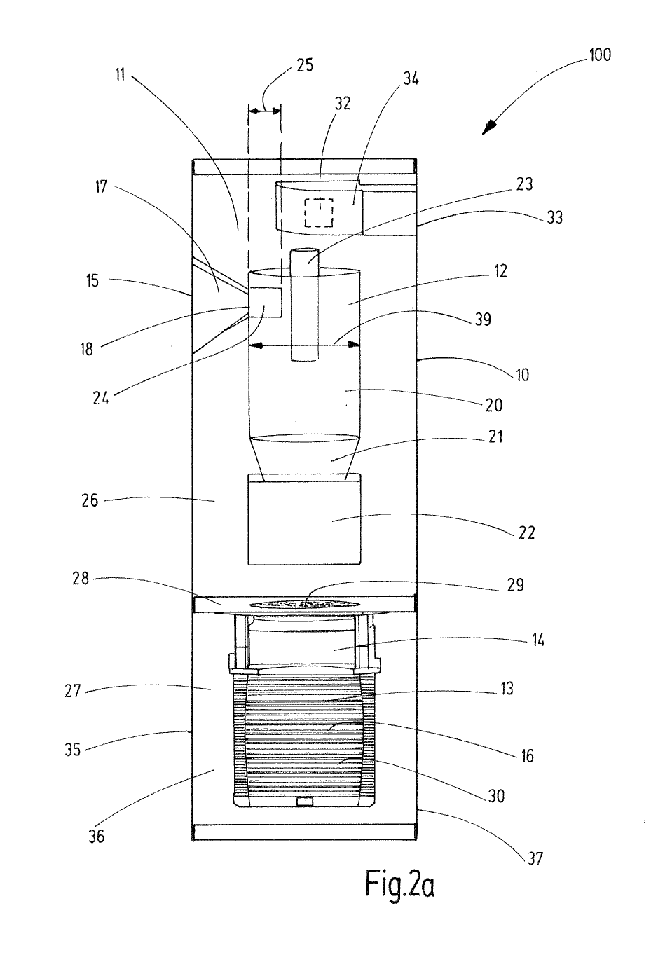

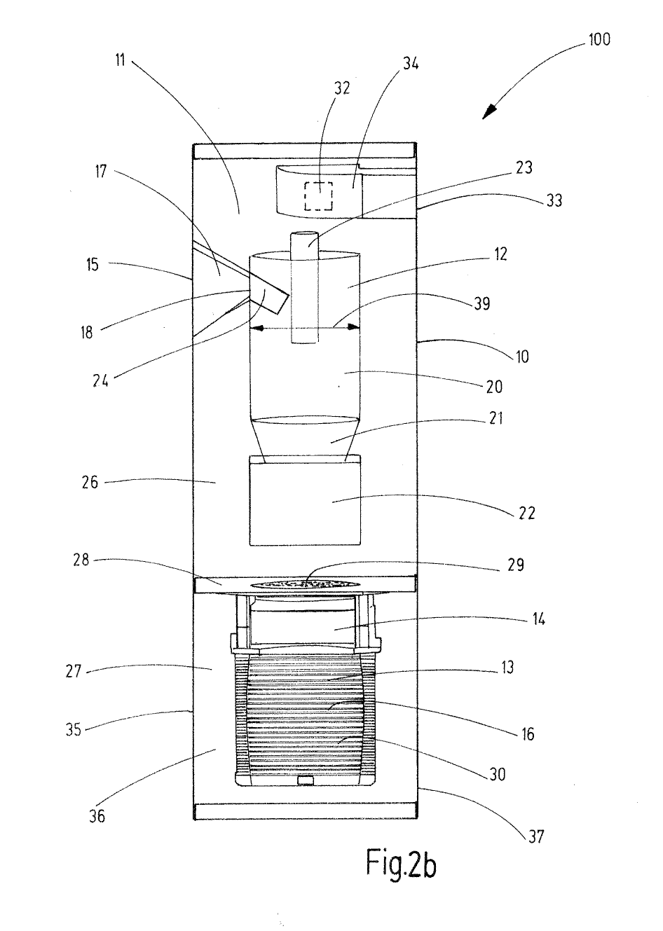

FIGS. 2a and 2b respectively show a further view of the air passage device 100 of FIG. 1. Here the first air purifying means 12 is shown to be at least partially transparent. As can be seen from FIGS. 2a and 2b, the entry duct 17 protrudes with its end region 24 over a first length 25 into the inflow cylinder 20 of the first air purifying means 12. The first length 25 over which the entry duct 17 protrudes with its end region 24 into the inflow cylinder, is configured to be shorter than half the diameter 39 of the inflow cylinder 20 of the first air purifying means 12. The immersion tube 23 of the first air purifying means 12 is arranged centrally in the upper area of the first air purifying means 12 or centrally in the inflow cylinder 20 of the first air purifying means 12. The end region 24 of the entry duct 17 is arranged at a distance from the immersion tube 23.

In FIG. 2a the entry duct 17 protrudes into the inflow cylinder 20 with its end region 24 vertically aligned to the side wall of the inflow cylinder 20.

In FIG. 2b the end region 24 of the entry duct 17 within the inflow cylinder 20 is obliquely inclined in a downward direction.

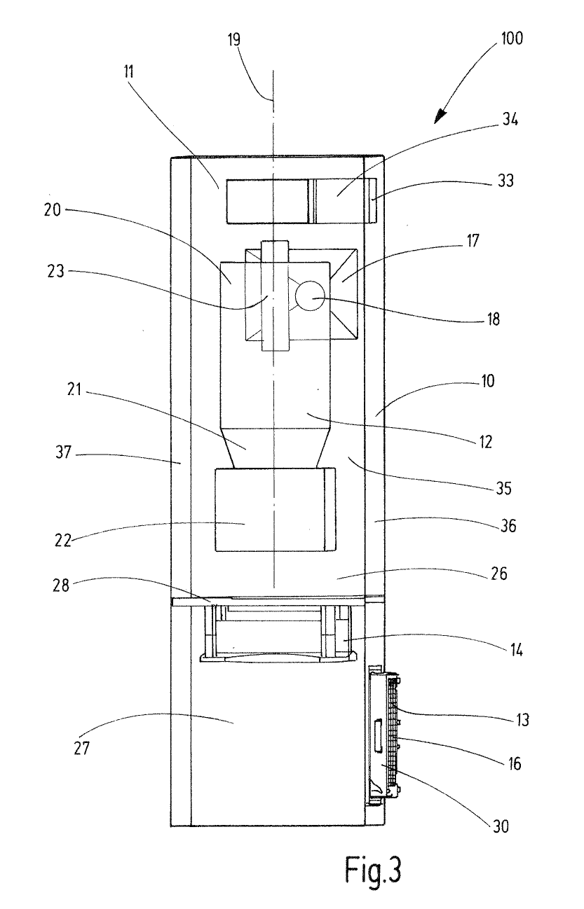

FIG. 3 shows a further view of the air passage device 100 of FIG. 1. As in FIGS. 2a and 2b the inflow cylinder 20 of the first air purifying means 12 is shown to be transparent. As shown in FIG. 3, in relation to the longitudinal central axis 19 of the inflow cylinder 20 of the first air purifying means 12, the inflow duct 17 or the end region 24 of the entry duct 17 protruding into the inflow cylinder 20 is arranged so as to be offset. Due to the offset arrangement of the end region 24 of the entry duct 17 in relation to the longitudinal central axis 19 of the inflow cylinder 20 a tangential inflow into the inflow cylinder 20 of the ambient air to be purified is achieved. Thus the air does not flow centrally relative to the longitudinal central axis 19 into the inflow cylinder 20, but is directed, offset, onto the inside wall of the inflow cylinder 20 of the first air purifying means 12.

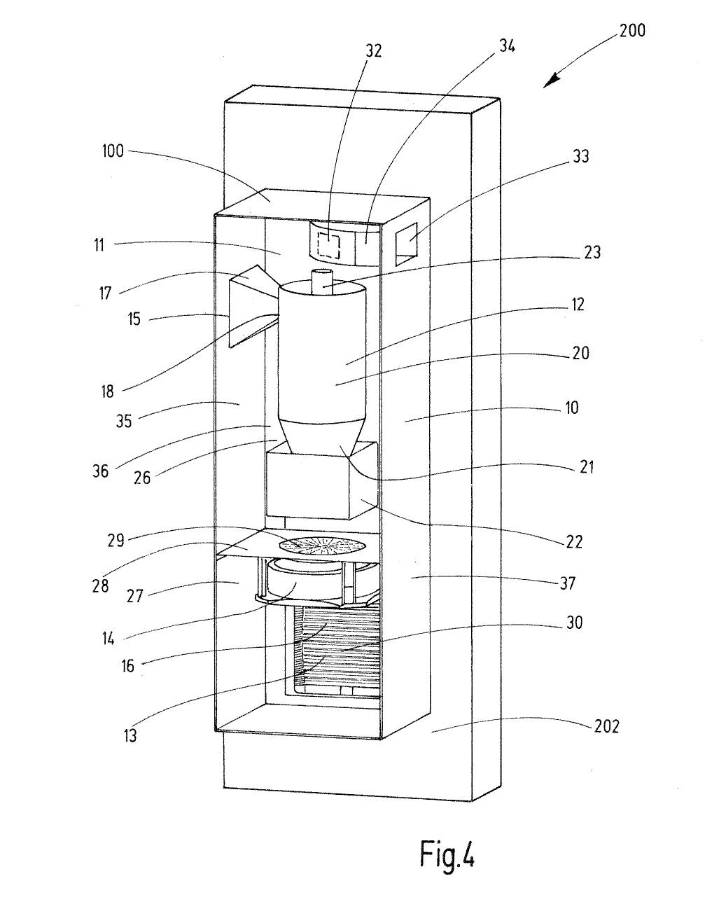

FIG. 4 shows a control cabinet 200 with an air passage device 100 arranged on the outside 202 thereof. The air passage device 100 with its second side wall 36 is firmly connected with the control cabinet outside 202.

What is claimed is:

1. An air passage device for admitting air, in particular ambient air, into an interior of a control cabinet or a computer housing, wherein the air passage device comprises a housing, wherein the air passage device comprises a first air purifying means for purifying the air to be passed through the air passage device, wherein an air conveying means is arranged on or in the housing of the air passage device for admitting the air to be purified by the first air purifying means, to the first air purifying means, characterised in that the first air purifying means is configured as a centrifugal separator.

2. The air passage device according to claim 1, characterised in that the air passage device comprises a first air inlet opening for the intake of air into an interior of the air passage device, wherein the air passage device comprises a first air outlet opening for discharging the purified air from the interior of the air passage device.

3. The air passage device according to claim 2, characterised in that the first air inlet opening is connected via an entry duct with an inlet opening of the first air purifying means for forwarding the air to the first air purifying means.

4. The air passage device according to claim 2, characterised in that the first air inlet opening of the air passage device is larger than an inlet opening of the first air purifying means.

5. The air passage device according to claim 3, characterised in that a cross-section of the entry duct decreases viewed from the first air inlet opening up to the inlet opening of the first air purifying means, wherein the cross-section of the entry duct preferably constantly decreases.

6. The air passage device according to one of claim 3, characterised in that the inlet opening of the first air purifying means or the entry duct is arranged so as to be offset, relative to a longitudinal central axis of the first air purifying means and/or of an inflow cylinder of the first air purifying means, to the tangential inflow of air into the inflow cylinder of the first air purifying means.

7. The air passage device according to one of claim 3, characterised in that an end region of the entry duct protrudes into the first air purifying means.

8. The air passage device according to claim 7, characterised in that the end region of the entry duct protruding into the first air purifying means is arranged so as to be offset, relative to a longitudinal central axis of the first air purifying means and/or of an inflow cylinder of the first air purifying means, to the tangential inflow of air into the inflow cylinder of the first air purifying means.

9. The air passage device according to one of the preceding claims, characterised in that an interior of the air passage device comprises a first area and a second area, wherein the first area is separated from the second area by a separating means.

10. The air passage device according to claim 9, characterised in that the separating means comprises at least one, preferably several, air passage apertures.

11. The air passage device according to claim 9, characterised in that the air conveying means is arranged on the separating means.

12. The air passage device according to one of claim 9, characterised in that the first area of the interior of the air passage device is under negative pressure in relation to the environment and/or in relation to the second area of the interior of the air passage device.

13. The air passage device according to one of claim 9, characterised in that the second area of the interior of the air passage device is under positive pressure in relation to the interior of the control cabinet and/or in relation to the first area of the interior of the air passage device.

14. The air passage device according to claim 13, characterised in that the air passage device comprises a second air purifying means which is preferably arranged in flow direction behind the first air purifying means.

15. The air passage device according to claim 14, characterised in that the second air purifying means comprises a filter, preferably a filter mat.

16. The air passage device according to claim 14, characterised in that the second air purifying means is configured as an exhaust filter or as a filter fan and is preferably arranged in the area of the first air outlet opening.

17. The air passage device according to one of claim 2, characterised in that the air passage device comprises a second air inlet opening for the intake of air from the interior of the control cabinet into the interior of the air passage device, wherein the air passage device comprises a second air outlet opening for the discharge of air sucked in from the interior of the control cabinet.

18. The air passage device according to claim 17, characterised in that the second air inlet opening and the second air outlet opening are connected with each other by a warm air duct.

19. A control cabinet comprising the air passage device according to claim 1.

20. A control cabinet according to claim 19 characterised in that the air passage device is arranged on a control cabinet outside.
